(19) United States
(12) Patent Application Publication
(10) Pub. No.: US 2025/0084309 A1
(43) Pub. Date: Mar. 13, 2025

(54) SEMICONDUCTOR PROCESSING SOLUTION

(71) Applicant: TOKUYAMA CORPORATION, Yamaguchi (JP)

(72) Inventors: Yuzan SUZUKI, Yamaguchi (JP); Yuki KIKKAWA, Yamaguchi (JP); Tomoaki SATO, Yamaguchi (JP)

(73) Assignee: TOKUYAMA CORPORATION, Yamaguchi (JP)

(21) Appl. No.: 18/707,255

(22) PCT Filed: Oct. 2, 2023
(86) PCT No.: PCT/JP2023/035958

§ 371 Date: May 3, 2024

(30) Foreign Application Priority Data
Oct. 3, 2022 (JP) 2022-159584

(51) Int. Cl. C09K 13/04; H01L 21/3213

(52) U.S. Cl. CPC C09K 13/04; H01L 21/32134

(57) ABSTRACT

Provided is a treatment liquid for a semiconductor to be used for removing a transition metal-containing substance on a substrate, the treatment liquid for a semiconductor containing a specific halogen oxyacid ion, at least one ion selected from the group consisting of a bromide ion, a bromite ion, a bromate ion, a chloride ion, a chlorate ion, an iodate ion, an iodide ion, and a triiodide ion, and at least one metal selected from the group consisting of Ca, Na, K, Cr, Ni, and Al, wherein a concentration of any one metal of Ca, Na, K, Cr, Ni, or Al is 0.1 ppt or more and 200 ppt or less.

### TECHNICAL FIELD

The present invention relates to a treatment liquid for a semiconductor used in a metal wiring treatment in a production process of a semiconductor element.

### BACKGROUND ART

In a semiconductor element, a wiring layer is formed for the purpose of taking out an electric signal generated by a transistor to the outside. Semiconductor elements have been increasingly miniaturized year by year. In a case where a material having low electromigration resistance or high resistance is used, the reliability of the semiconductor element is reduced or high-speed operation is inhibited. Thus, a material having higher electromigration resistance and a low resistance value is desired as a wiring material.

As such a material having high electromigration resistance and a low resistance value, for example, aluminum and copper have been used, and recently, tungsten, cobalt, molybdenum, and ruthenium have been examined. In a case where a wiring layer is formed on a semiconductor element, a step of processing a wiring material is included, and dry or wet etching is used in this step.

In a case where a wiring material is wet-etched, when the surface state after etching is rough, there is a problem that when a metal film is newly formed thereon, the electric resistance increases and the electric characteristics deteriorate.

Thus, there is a demand for a treatment liquid capable of maintaining a smooth surface state after wet-etching. As a method of maintaining a smooth surface state after etching, there is a method of newly adding an additive to a treatment liquid, and modifying the surface state by the additive, and thereby controlling etching performance are considered. In addition, when the stability of an etching rate is good, there is little variation in an etching amount on a wafer or for every wafer, and yield is less likely to occur.

In Patent Document 1, an additive capable of inhibiting deterioration of a surface state after etching is studied. In the invention described in this document, a predetermined amount of chlorite ions to hypochlorite ions is added to the treatment liquid used for etching. The addition of chlorite ions makes it possible to control an oxidation-reduction potential, which is considered to be effective for smoothness of the surface state of a metal wiring after the treatment.

### PRIOR ART DOCUMENTS

### Patent Document

Patent Document 1: JP 2019-218436 A

### SUMMARY OF INVENTION

### Technical Problem

The present inventors have studied the removability of a transition metal-containing substance and the stability of an etching rate by using the method disclosed in Patent Document 1. It has been found that although there is an excellent dissolving ability, smoothness of a treated portion is not sufficient, and a hypochlorite ion and a chlorite ion react with each other to decompose the hypochlorite ion, whereby the stability of the etching rate is more insufficient. Thus, further improvement is required.

In a wet-etching step of a semiconductor wafer, in addition to the smoothness of the surface state of the metal wiring after the treatment, the stability of the etching rate for the transition metal-containing substance is required. When the stability of the etching rate is poor, there is a possibility that a variation in the etching amount occurs on a wafer or for every wafer depending on a storage period and the yield rate increases.

Accordingly, an object of the present invention is to provide a treatment liquid which has an excellent ability to dissolve a transition metal-containing substance, can realize excellent smoothness, and achieves a stable etching rate.

### Solution to Problem

The present inventors conducted diligent research to solve the above problems. The present inventors have found that the above problems can be solved by a treatment liquid for a semiconductor containing at least one halogen oxyacid ion selected from the group consisting of a hypobromite ion, a hypochlorite ion, and a periodate ion, at least one ion selected from the group consisting of a bromide ion, a bromite ion, a bromate ion, a chloride ion, a chlorate ion, an iodate ion, an iodide ion, and a triiodide ion, and at least one metal selected from the group consisting of Ca, Na, and K. The result has been obtained in which when at least one metal selected from the group consisting of Ca, Na, and K is contained, smoothness of a treated portion is maintained, and when at least one ion selected from the group consisting of a bromide ion, a bromite ion, a bromate ion, a chloride ion, a chlorate ion, an iodate ion, an iodide ion, and a triiodide ion is contained, the etching rate of the treatment liquid is stable, leading to completion of the present invention. That is, the present invention is configured as follows.

Aspect 1. A treatment liquid for a semiconductor to be used for removing a transition metal-containing substance on a substrate, the treatment liquid containing:
at least one halogen oxyacid ion selected from the group consisting of a hypobromite ion, a hypochlorite ion, and a periodate ion;
at least one ion selected from the group consisting of a bromide ion, a bromite ion, a bromate ion, a chloride ion, a chlorate ion, an iodate ion, an iodide ion, and a triiodide ion; and
at least one metal selected from the group consisting of Ca, Na, K, Cr, Ni, and Al, wherein
a concentration of any one metal of Ca, Na, K, Cr, Ni, or Al is 0.1 mass ppt or more and 200 mass ppt or less.

Aspect 2. The treatment liquid for a semiconductor according to Aspect 1, wherein
a ratio of a concentration of any one ion of a bromide ion, a bromite ion, a bromate ion, a chloride ion, or a chlorate ion to a concentration of any one metal of Ca, Na, K, Cr, Ni, or Al is 1 or more and 1×10⁸ or less, and
a hypobromite ion is contained.

Aspect 3. The treatment liquid for a semiconductor according to Aspect 1 or 2, wherein the metal is Ca, Na, and K.

Aspect 4. The treatment liquid for a semiconductor according to Aspect 1, the treatment liquid for a semiconductor containing:
at least one ion selected from the group consisting of a bromide ion, a bromite ion, and a bromate ion;
at least one metal selected from the group consisting of Ca, Na, and K; and a hypobromite ion.

Aspect 5. The treatment liquid for a semiconductor according to Aspect 3 or 4, wherein a pH of the treatment liquid for a semiconductor is 10.0 or higher and 13.0 or lower.

Aspect 6. The treatment liquid for a semiconductor according to Aspect 3 or 4, the treatment liquid containing
a bromate ion, wherein
a ratio of a concentration of a bromate ion to a total concentration of Ca, Na, and K is 1 or more and 1×10⁸ or less.

Aspect 7. The treatment liquid for a semiconductor according to Aspect 3 or 4, the treatment liquid containing
at least one ion selected from the group consisting of a bromide ion, a bromite ion, and a bromate ion, wherein
a ratio of a concentration of a bromide ion, a bromite ion, or a bromate ion to a total concentration of Cr, Ni, and Al is 1 or more and 1×10⁸ or less.

Aspect 8. The treatment liquid for a semiconductor according to Aspect 1, wherein
a ratio of a concentration of any one ion of a chloride ion or a chlorate ion to a concentration of any one metal of Ca, Na, K, Cr, Ni, or Al is 1 or more and 1×10⁸ or less, and
a hypochlorite ion is contained.

Aspect 9. The treatment liquid for a semiconductor according to Aspect 1, the treatment liquid containing:
at least one ion selected from the group consisting of a chloride ion and a chlorate ion;
at least one metal selected from the group consisting of Ca, Na, and K; and
a hypochlorite ion.

Aspect 10. The treatment liquid for a semiconductor according to Aspect 8 or 9, wherein a pH of the treatment liquid for a semiconductor is 10.0 or higher and 13.0 or less.

Aspect 11. The treatment liquid for a semiconductor according to Aspect 8 or 9, the treatment liquid containing
a chlorate ion, wherein
a ratio of a concentration of a chlorate ion to a total concentration of Ca, Na, and K is 1 or more and 1×10⁸ or less.

Aspect 12. The treatment liquid for a semiconductor according to Aspect 8 or 9, the treatment liquid containing
a chloride ion, wherein
a ratio of a concentration of a chloride ion to a total concentration of Cr, Ni, and Al is 1 or more and 1×10⁸ or less.

Aspect 13. The treatment liquid for a semiconductor according to Aspect 1, wherein
a ratio of a concentration of any one ion of an iodate ion, an iodide ion, or a triiodide ion to a concentration of any one metal of Ca, Na, K, Cr, Ni, or Al is 1 or more and 1×10⁸ or less, and
a periodate ion is contained.

Aspect 14. The treatment liquid for a semiconductor according to Aspect 1, the treatment liquid containing:
at least one ion selected from the group consisting of an iodate ion, an iodide ion, and a triiodide ion;
at least one metal selected from the group consisting of Ca, Na, and K; and a periodate ion.

Aspect 15. The treatment liquid for a semiconductor according to Aspect 13 or 14, wherein a pH of the treatment liquid for a semiconductor is 8.5 or higher and 11.0 or lower.

Aspect 16. The treatment liquid for a semiconductor according to Aspect 14 or 15, the treatment liquid containing
an iodate ion, wherein
a ratio of a concentration of an iodate ion to a total concentration of Ca, Na, and K is 1 or more and 1×10⁸ or less.

Aspect 17. The treatment liquid for a semiconductor according to Aspect 14 or 15, the treatment liquid containing
an iodide ion, wherein
a ratio of a concentration of an iodide ion to a total concentration of Cr, Ni, and Al is 1 or more and 1×10⁸ or less.

### Effects of Invention

According to the present invention, when a certain type of metal and a certain type of ion are preferably added at a specific concentration or concentration ratio, it is possible to provide a treatment liquid for a semiconductor which achieves excellent smoothness and can achieve a stable etching rate for a treated portion of a transition metal-containing substance.

### BRIEF DESCRIPTION OF DRAWINGS

FIG. 1 is a diagram schematically illustrating equipment used in an etching step in a method for producing a semiconductor element.

### DESCRIPTION OF EMBODIMENTS

### (Treatment Liquid for Semiconductor)

A treatment liquid for a semiconductor of the present embodiment is characterized by containing a target mixture described below. The treatment liquid for a semiconductor according to an embodiment of the present invention is also referred to as a treatment liquid.

The target mixture is a mixture in which a specific ion and a specific metal are present. The specific ion is an ion containing at least one ion selected from the group consisting of a bromide ion, a bromite ion, a bromate ion, a chloride ion, a chlorate ion, an iodate ion, an iodide ion, and a triiodide ion, and a halogen oxyacid ion described below. The specific metal is at least one metal selected from the group consisting of Ca, Na, K, Cr, Ni, and Al.

### (Treatment Target)

When the treatment liquid of the present embodiment is used, the smoothness of a substrate surface and the stability of an etching rate (which may be referred to simply as “stability” in the present specification) can be maintained, although the mechanism is not clear. The smoothness and the stability of the etching rate are attributed to the difference in a surface oxidation state of a transition metal-containing substance on a wafer. The semiconductor wafer suitably contains at least one transition metal selected from Ru, Rh, Ti, Ta, Co, Cr, Hf, Os, Pt, Ni, Mn, Cu, Zr, La, Mo, and W, and further preferably contains Ru, Mo, and W.

It is surmised that when the treatment liquid of the present embodiment is used, a target mixture is adsorbed on the surface of the transition metal-containing substance to adjust an oxidation state, and thus the smoothness of the substrate surface and the stability of the etching rate can be maintained.

The specific metal is usually a substance contained in the semiconductor treatment liquid as an impurity. When particles of such a metal remain on a fine metal wiring, they may cause a short circuit or a like problem to greatly affect a semiconductor element. Thus, it has been considered that an amount of a metal element in the treatment liquid is preferably as small as possible. However, JP 2019-142788 A and JP 2017-169832 A disclose that a metal amount in the treatment liquid does not necessarily correlate with a metal amount on the wafer. Accordingly, it is considered that an influence such as a short circuit caused by metal particles due to addition of a trace amount of metal hardly occurs.

### (Halogen Oxyacid Ion)

The treatment liquid of the present embodiment contains at least one halogen oxyacid ion selected from the group consisting of a hypobromite ion, a hypochlorite ion, and a periodate ion. The halogen oxyacid ion functions as an oxidizing agent. The concentration of the halogen oxyacid ion is not particularly limited without departing from the object of the present invention, but is preferably 50 mass ppm or more and 35.0 mass % or less.

In a case where a hypobromite ion or a hypochlorite ion is selected as the halogen oxyacid ion contained in the treatment liquid of the present embodiment, the concentration thereof is not particularly limited, but is preferably 50 mass ppm or more and 5.0 mass % or less, more preferably 500 mass ppm or more and 2.0 mass % or less, and still more preferably 500 mass ppm or more and 5000 mass ppm or less relative to the total mass of the treatment liquid from the viewpoint that it is possible to dissolve a transition metal.

In a case where a periodate ion is selected as the halogen oxyacid ion contained in the treatment liquid of the present embodiment, there is no particular limitation, but an orthoperiodate ion or a metaperiodate ion is preferable from the viewpoint that it is possible to dissolve a transition metal. In addition, a salt of orthoperiodic acid and a salt of metaperiodic acid can be used because they are ionized when dissolved in water. In particular, an orthoperiodate ion is more preferable because it does not contain Na and has a stable composition.

In view of the dissolving ability of the treatment liquid, the content of the periodate ion is preferably 0.5 mass % or more and 35.0 mass % or less and more preferably 2.0 mass % or more and 8.0 mass % or less relative to the total mass of the treatment liquid.

The halogen oxyacid ion contained in the treatment liquid of the present embodiment can be one type or two or more types. When a plurality of types are contained, there is a possibility that the etching rate is stabilized and the stability at the time of reuse is improved. For example, in a case where a hypobromite ion is contained as the first type of the halogen oxyacid ion, a bromide ion is generated when consumption by oxidation or decomposition by disproportionation proceeds. A decrease in the concentration of the halogen oxyacid ion causes a decrease in the etching rate.

However, when the treatment liquid contains a hypochlorite ion as the second type of the halogen oxyacid ion, the generated bromide ion can be oxidized to be changed into a hypobromite ion. This makes it easier to stabilize the etching rate.

For the reasons described above, in a case where the treatment liquid of the present embodiment contains a hypobromite ion, a hypochlorite ion preferably coexists. The concentration of the hypochlorite ion is not limited without departing from the spirit of the present invention, but is preferably 50 mass ppm or more and 5 mass % or less. When the concentration of the hypochlorite ion is less than 50 mass ppm, the treatment liquid cannot efficiently oxidize Br⁻, reducing the etching rate of ruthenium. Meanwhile, when the added amount of the hypochlorite ion is greater than 5 mass %, the stability of the hypochlorite ion decreases, and decomposition of the hypobromite ion is promoted by the reaction between the hypochlorite ion and the hypobromite ion, which is not appropriate. The concentration of the hypochlorite ion is preferably 50 mass ppm or more and 5 mass % or less, more preferably 500 mass ppm or more and 2 mass % or less, and still more preferably 500 mass ppm or more and 5000 mass ppm or less.

### (Specific Ion)

As described above, the treatment liquid of the present embodiment contains the target mixture. The target mixture contains a specific ion. The specific ion contained in the treatment liquid of the present embodiment includes at least one ion selected from the group consisting of a bromide ion, a bromite ion, a bromate ion, a chloride ion, a chlorate ion, an iodate ion, an iodide ion, and a triiodide ion, and a halogen oxyacid ion. The halogen oxyacid ion is at least one halogen oxyacid ion selected from the group consisting of a hypobromite ion, a hypochlorite ion, and a periodate ion.

The bromide ion can be contained in the treatment liquid by, for example, bromine gas, hydrogen bromide, or a bromine salt. The content of the bromide ion can be adjusted by the weight of bromine gas, hydrogen bromide, or a bromine salt added to the treatment liquid.

The bromite ion can be contained in the treatment liquid by, for example, bromous acid or a bromite. The bromite can be any salt as long as the counter cation of a bromite ion does not react with the halogen oxyacid ion or does not interfere with the present invention even when it reacts with the halogen oxyacid ion. Examples of the bromite include those described below. The content of the bromite ion can be adjusted by the weight of bromous acid or a bromite added to the treatment liquid.

The bromate ion can be contained in the treatment liquid by, for example, bromic acid or a bromate. The content of the bromate ion can be adjusted by the weight of bromic acid or a bromate added to the treatment liquid.

The chloride ion can be contained in the treatment liquid by, for example, chlorine gas, hydrogen chloride, or a chlorine salt. The content of the chloride ion can be adjusted by the weight of chlorine gas, hydrogen chloride, or a chlorine salt added to the treatment liquid.

The chlorate ion can be contained in the treatment liquid by, for example, chloric acid or a chlorate. The content of the chlorate ion can be adjusted by the weight of chloric acid or a chlorate added to the treatment liquid.

The iodate ion can be contained in the treatment liquid by, for example, an iodate. The content of the iodate ion can be adjusted by the weight of an iodate added to the treatment liquid.

The iodide ion can be contained in the treatment liquid by, for example, iodine, iodine gas, hydrogen iodide, or an iodine salt. The content of the iodide ion can be adjusted by the weight of iodine, iodine gas, hydrogen iodide, or an iodine salt added to the treatment liquid.

The triiodide ion can be contained in the treatment liquid by, for example, a triiodide. The content of the triiodide ion can be adjusted by the weight of a triiodide added to the treatment liquid.

A plurality of combinations of the halogen oxyacid ion and the specific ion contained in the treatment liquid of the present embodiment are conceivable, but a preferable specific ion is present for every halogen oxyacid ion. When a preferable specific ion is selected for the halogen oxyacid ion, the storage stability of the treatment liquid is further improved. This is considered to be because a disproportionation reaction of the halogen oxyacid ion is inhibited. The specific ion selected at this time can be one type or two or more types. In a case where two or more types of specific ions are selected, the total concentration of the specific ions is preferably 0.01 mass ppt or more and 2 mass % or less, preferably 1 mass ppb or more and 1 mass % or less, and more preferably 10 mass ppb or more and 0.1 mass % or less, relative to the total mass of the treatment liquid.

In a case where a hypobromite ion is selected as the halogen oxyacid ion, the specific ion is preferably a bromate ion, a bromite ion, a bromide ion, a chlorate ion, a chloride ion, or an iodate ion, and more preferably a bromate ion, a bromide ion, a chloride ion, or a chlorate ion.

In a case where a hypochlorite ion is selected as the halogen oxyacid ion, the specific ion is preferably a chlorate ion, a chloride ion, a bromate ion, a bromite ion, or an iodate ion, and more preferably a chlorate ion or a chloride ion.

In a case where a periodate ion is selected as the halogen oxyacid ion, the specific ion is preferably an iodate ion, an iodide ion, a triiodide ion, a bromide ion, or a chloride ion, and more preferably an iodate ion, an iodide ion, or a triiodide ion.

Even in a case where two or more types of halogen oxyacid ions are selected, there is a preferred specific ion as the specific ion to be selected. In a case where a hypochlorite ion and a hypobromite ion are selected as the halogen oxyacid ion, the specific ion is preferably a bromate ion, a bromite ion, a bromide ion, a chlorate ion, a chloride ion, or an iodate ion, and more preferably a bromate ion, a bromide ion, a chloride ion, or a chlorate ion.

In a case where a salt is selected for incorporating a specific ion, the counter cation can be any salt as long as it does not react with the halogen oxyacid ion or does not interfere with the present invention even when it reacts with the halogen oxyacid ion. There is no particular limitation, and examples of the chloride ion can include lithium chloride, sodium chloride, potassium chloride, rubidium chloride, cesium chloride, ammonium chloride, and onium chloride. The onium chloride referred to here is a compound formed of an onium ion and a chloride ion. An onium ion is a compound of a polyatomic cation formed by addition of excess protons (hydrogen cations) to a monatomic anion. Specifically, the onium ion is a cation, such as an imidazolium ion, a pyrrolidinium ion, a pyridinium ion, a piperidinium ion, an ammonium ion, a phosphonium ion, a fluoronium ion, a chloronium ion, a bromonium ion, an iodonium ion, an oxonium ion, a sulfonium ion, a selenonium ion, a telluronium ion, an arsonium ion, a stibonium ion, or a bismuthonium ion. The salt is preferably a salt formed with an onium ion, and more preferably a compound containing a hydrogen ion, for the reason that the metal amount in the treatment liquid is not changed.

From the viewpoint of excellent stability of the etching rate of the treatment liquid, the content of the specific ion is preferably 0.01 mass ppt or more and 2 mass % or less, more preferably 1 mass ppb or more and 1 mass % or less, and still more preferably 10 mass ppb or more and 0.1 mass % or less, relative to the total mass of the treatment liquid. This concentration range is applicable to any of the specific ions described above.

All of the specific ions are anions, and a cation serving as a counter ion is present in the treatment liquid.

As the cation, for example, a hydrogen cation (H), a tetraalkylammonium cation (e.g., a tetramethylammonium cation (TMA⁺), a tetraethylammonium cation (TEA⁺), an ethyltrimethylammonium cation (ETMA⁺), or a tetrabutylammonium cation (TBA⁺)), or an ammonium ion (NH₄⁺) is preferable, and a hydrogen cation (H⁺) or a tetramethylammonium cation (TMA⁺) is more preferable.

### (Specific Metal)

As described above, the treatment liquid of the present embodiment contains the target mixture. The target mixture contains a specific metal in addition to the specific ion. The specific metal is at least one selected from the group consisting of Ca, Na, K, Cr, Ni, and Al. Although the mechanism is not clear, it is considered that the target mixture in the form of a cation is adsorbed on the surface of the transition metal-containing substance to make the oxidation state uniform, and thus it is considered that there is an effect on the surface smoothness in the etching of the transition metal. Ca, Na, or K, which has a high ionization tendency, is preferable as a metal selected from these metals. Even when Cr, Ni, or Al is contained in the treatment liquid of the present embodiment, similar to the case where Ca, Na, or K is contained, the effect regarding the surface smoothness can be obtained, but the effect is higher in the case where Ca, Na, or K, which has a high ionization tendency, is contained.

From the viewpoint of excellent smoothness of the treatment liquid, the content of the specific metal is 0.01 mass ppt or more and 200 mass ppt or less, preferably 0.01 mass ppt or more and 100 mass ppt or less, and more preferably 0.01 mass ppt or more and 50 mass ppt or less, relative to the total mass of the treatment liquid.

Among the above-described metals, the concentration of each of the metals of Na, K, and Ca is preferably 0.01 mass ppt or more and 200 mass ppt or less. Furthermore, among the above-described metals, the total concentration of all the metals of Na, K, and Ca is 0.01 mass ppt or more and 600 mass ppt or less, preferably 0.01 mass ppt or more and 300 mass ppt or less, and more preferably 0.01 mass ppt or more and 150 mass ppt or less, relative to the total mass of the treatment liquid.

Among the above-described metals, the total concentration of all the metals of Cr, Ni, and Al is 0.01 mass ppt or more and 600 mass ppt or less, preferably 0.01 mass ppt or more and 300 mass ppt or less, and more preferably 0.01 mass ppt or more and 150 mass ppt or less, relative to the total mass of the treatment liquid.

A concentration ratio of the specific ion to each specific metal is preferably 1 or more and 1×10⁸ or less from the viewpoint of excellent stability of the etching rate of the treatment liquid.

The treatment liquid of the present embodiment can contain Fe, Zn, or Cu in addition to the specific metal described above. In a case where Fe, Zn, or Cu is contained, the content of each of these metals is 0.01 mass ppt or more and 200 mass ppt or less, preferably 0.01 mass ppt or more and 100 mass ppt or less, more preferably 0.01 mass ppt or more and 50 mass ppt or less, relative to the total mass of the treatment liquid.

### (Combination of Specific Ion and Specific Metal)

The treatment liquid shown in each of the following specific examples contains at least one selected from the group consisting of Ca, Na, K, Cr, Ni, and Al.

In the treatment liquid of a first specific example of the present embodiment, a ratio of a concentration of any one ion of a bromide ion, a bromite ion, a bromate ion, a chloride ion, or a chlorate ion to a concentration of any one metal of Ca, Na, K, Cr, Ni, or Al is preferably 1 or more and 1×10⁸ or less. The upper limit of the concentration ratio is preferably 2.4×10⁷, and more preferably 1×10⁵.

In the treatment liquid of a second specific example of the present embodiment, a ratio of a concentration of any one ion of a bromide ion, a bromite ion, or a bromate ion to a total concentration of Ca, Na, and K is preferably 1 or more and 1×10⁸. The upper limit of the concentration ratio is preferably 2.4×10⁷, and more preferably 1×10⁵. In this specific example, it is preferred that the treatment liquid contains all of Ca, Na, and K.

In two specific examples of the first and second specific examples, the pH of the treatment liquid for a semiconductor is preferably 10.0 or higher and 13.0 or lower.

The treatment liquid of a third specific example of the present embodiment preferably contains a bromate ion, and a ratio of a concentration of a bromate ion to the total concentration of Ca, Na, and K is preferably 1 or more and 1×10⁸ or less. The upper limit of the concentration ratio is preferably 9.7×10⁶, and more preferably 1×10⁵. In this specific example, it is preferred that the treatment liquid contains all of Ca, Na, and K.

A fourth treatment liquid of the present embodiment contains at least one ion selected from the group consisting of a bromide ion, a bromite ion, and a bromate ion, and a ratio of a concentration of a bromide ion, a bromite ion, or a bromate ion to a total concentration of Cr, Ni, and Al is preferably 1 or more and 1×10⁸ or less. The upper limit of the concentration ratio is preferably 6.0×10⁵, and more preferably 5.0×10⁵. In this specific example, it is preferred that the treatment liquid contains all of Cr, Ni, and Al.

In the treatment liquid of a fifth specific example of the present embodiment, a ratio of a concentration of any one ion of a chloride ion or a chlorate ion to a concentration of any one metal of Ca, Na, K, Cr, Ni, or Al is preferably 1 or more and 1×10⁸ or less. The upper limit of the concentration ratio is preferably 2.3×10⁶, and more preferably 1×10⁵.

The treatment liquid of a sixth specific example of the present embodiment preferably contains at least one ion selected from the group consisting of a chloride ion and a chlorate ion, at least one metal selected from the group consisting of Ca, Na, and K, and a hypochlorite ion.

In the treatment liquid of a seventh specific example of the present embodiment, a ratio of a concentration of any one ion of a chloride ion or a chlorate ion to a total concentration of Ca, Na, and K is preferably 1 or more and 1×10⁸ or less. The upper limit of the concentration ratio is preferably 2.3×10⁶, and more preferably 1×10⁵. In this specific example, it is preferred that the treatment liquid contains all of Ca, Na, and K.

The pH of the treatment liquid of each of the sixth and seventh specific examples is preferably 10.0 or higher and 13.0 or lower.

The treatment liquid of an eighth specific example of the present embodiment preferably contains a chlorate ion, and a ratio of a concentration of the chlorate ion to a total concentration of Ca, Na, and K is preferably 1 or more and 1×10⁸ or less. The upper limit of the concentration ratio is preferably 2.6×10⁷, and more preferably 1×10⁵. In this specific example, it is preferred that the treatment liquid contains all of Ca, Na, and K.

The treatment liquid of a ninth specific example of the present embodiment preferably contains a chloride ion, and a ratio of a concentration of the chloride ion to a total concentration of Cr, Ni, and Al is preferably 1 or more and 1×10⁸ or less. The upper limit of the concentration ratio is preferably 6.0×10⁵, and more preferably 5.5×10⁵. In this specific example, it is preferred that the treatment liquid contains all of Cr, Ni, and Al.

In the treatment liquid of a tenth specific example of the present embodiment, a ratio of a concentration of any one ion of an iodate ion, an iodide ion, or a triiodide ion to a concentration of any one metal of Ca, Na, K, Cr, Ni, or Al is preferably 1 or more and 1×10⁸ or less, and the treatment liquid preferably contains a periodate ion. The upper limit of the concentration ratio is preferably 1.8×10⁷, and more preferably 1×10⁵.

The treatment liquid of an eleventh specific example of the present embodiment preferably contains at least one ion selected from the group consisting of an iodate ion, an iodide ion, and a triiodide ion, at least one metal selected from the group consisting of Ca, Na, and K, and a periodate ion.

In the treatment liquid of a twelfth specific example, a concentration of any one ion of an iodate ion, an iodide ion, or a triiodide ion is preferably 1 mass ppb or more and 1 mass % or less.

The pH of the treatment liquid of each of the tenth and eleventh specific examples is preferably 8.5 or higher and 11.0 or lower.

In each of the treatment liquids of the tenth and eleventh specific examples, a ratio of a concentration of the iodate ion to a total concentration of Ca, Na, and K is preferably 1 or more and 1×10⁸ or less. The upper limit of the concentration ratio is preferably 1.9×10⁷, and more preferably 1×10⁵.

The treatment liquid of a thirteenth specific example of the present embodiment preferably contains an iodide ion, and a ratio of a concentration of the iodide ion to a total concentration of Cr, Ni, and Al is preferably 1 or more and 1×10⁸ or less. The upper limit of the concentration ratio is preferably 5.5×10⁵, and more preferably 5.0×10⁵. In this specific example, it is preferred that the treatment liquid contains all of Cr, Ni, and Al.

(pH)

The pH of the treatment liquid of the present embodiment is preferably 8.5 to 13.0. Within this range, there is a preferable pH range depending on the selected halogen oxyacid ion. Specifically, the pH range is as described in each of the above specific examples. The reason why the preferable pH range exists is that when the pH is too low, the storage stability of the halogen oxyacid ion becomes poor, and when the pH is too high, the etching rate for the transition metal becomes low. The storage stability is evaluated as a change in the concentration of a halogen oxyacid ion when the treatment liquid is stored for a long period of time.

In a case where a periodate ion is contained as the halogen oxyacid ion in the treatment liquid of the present embodiment, the pH is preferably 8.5 to 11.0, and more preferably 9.0 to 10.0 from the viewpoint of dissolving ability, smoothness, storage stability, and the stability of the etching rate.

In a case where any one or more of a hypobromite ion or a hypochlorite ion are selected as the halogen oxyacid ion contained in the treatment liquid of the present embodiment, the pH is preferably 10.0 to 13.0, and more preferably 12.0 to 12.6 from the viewpoint of dissolving ability, smoothness, storage stability, and the stability of the etching rate.

### (Others)

The treatment liquid according to the present embodiment can contain an additional additive that has been used in a treatment liquid for a semiconductor in the related art, as long as the object of the present invention is not impaired. Examples of the additional additive that can be added include an acid, a metal anticorrosive, a water-soluble organic solvent, a fluorine compound, a reducing agent, a complexing agent, a chelating agent, a surfactant, an antifoaming agent, a pH adjuster, and a stabilizer. Such an additive can be added alone, or a plurality of additives can be added in combination.

As the pH adjuster, an acid or an alkali can be added to the treatment liquid of the present embodiment. As the alkali, an organic alkali is preferably used because it does not contain a metal ion, which is problematic in semiconductor production. In particular, the organic alkali is preferably tetraalkylammonium hydroxide and more preferably tetramethylammonium hydroxide because it provides a large number of hydroxide ions per unit weight and a high-purity product is readily available.

The water contained in the treatment liquid of the present embodiment is preferably water from which metal ions, organic impurities, or particles have been removed by distillation, ion exchange treatment, filtration, or any type of adsorption treatment, and pure water or ultrapure water is particularly preferable. Such water can be obtained by a known method widely used in semiconductor manufacturing.

The temperature at which ruthenium is etched using the semiconductor treatment liquid of the present embodiment is not particularly limited, but can be determined in consideration of an etching rate of ruthenium, or an amount of RuO₄ gas generated. In a case where the treatment temperature is high, the amount of RuO₄ gas increases, and the stability of the halogen oxyacid ion decreases. Meanwhile, a decrease in the temperature tends to cause a decrease in the etching rate. For such a reason, the temperature for etching ruthenium is preferably from 10° C. to 90° C., more preferably from 15° C. to 60° C., and most preferably from 25° C. to 45° C.

The treatment liquid of the present embodiment is preferably stored at a low temperature and/or under a light-shielded condition. Storage at a low temperature and/or under a light-shielded condition is expected to provide an effect of inhibiting decomposition of the oxidizing agent in the treatment liquid. Furthermore, the stability of the treatment liquid can be maintained by storing the treatment liquid in a container filled with an inert gas to prevent contamination of carbon dioxide. In addition, the inner surface of the container, that is, the surface to be in contact with the treatment liquid, is preferably formed of glass or an organic polymer material. This is because the container having an inner surface formed of glass or an organic polymer material can further reduce contamination of impurities, such as a metal, a metal oxide, or an organic material.

### (Smoothing Agent for Filtration)

The treatment liquid of the present embodiment can contain an onium ion as a smoothing agent for filtration. When the smoothing agent for filtration has a low surface tension, there is a possibility that the smoothing agent is removed in the filtration step. Thus, the surface tension of the smoothing agent for filtration is desirably 60 mN/m or more and 75 mN/m or less. When the onium ion interacts with the metal surface of a semiconductor wafer, roughening of the metal surface can be inhibited. Further, in a case where ruthenium is contained in the semiconductor wafer, the onium ion interacts with RuO₄ or RuO₄²⁻ generated at the time of etching of ruthenium, whereby generation of RuO₄ gas and RuO₂ particles generated concomitantly can be inhibited.

As described above, the onium ion contained in the smoothing agent for filtration used in the present embodiment plays various roles, and the surface tension of the smoothing agent for filtration is a key to highly maintaining these effects. That is, when the surface tension of the smoothing agent for filtration is less than 60 mN/m, the onium ion contained in the smoothing agent for filtration is easily removed by the filtration step, and thus it is difficult to maintain the good surface smoothness and the effect of inhibiting the RuO₄ gas as described above. One method of increasing the surface tension involves adding a large amount of salt. However, in a case where an oxidizing agent described below is contained in the smoothing agent for filtration used in the present embodiment, the salt and the oxidizing agent may react with each other to decrease the stability of the oxidizing agent, or the salt at a high concentration may inhibit etching. For such a reason, the surface tension is preferably 75 mN/m or less.

The filtration step will now be described. In the production of a semiconductor wafer, adhesion of particles to a wafer causes a decrease in yield, and thus the treatment liquid is filtered for the purpose of removing particles in the treatment liquid. In a case of a state-of-the-art semiconductor wafer, a wiring width is as fine as several nm to several tens of nm, and thus a filter used in the filtration step is also required to have a similar pore size. However, when the pore size of the filter becomes smaller, the onium salt or the onium ion is more easily adsorbed and removed. As a result, the onium ion concentration in the treatment liquid decreases to impair the function as the treatment liquid described above.

However, such a decrease in the concentration of the onium ion can be avoided by controlling the surface tension of the smoothing agent for filtration. Specifically, the surface tension of water is about 73 mN/m at 25° C., and it is possible to inhibit the adsorption of an onium salt or an onium ion to the filter by bringing the surface tension of the smoothing agent for filtration close to this value. That is, when the surface tension of the smoothing agent for filtration is controlled to be 60 mN/m or more and 75 mN/m or less, the adsorption of the onium salt or the onium ion to the filter is inhibited, and the smoothing agent for filtration can be used as the treatment liquid without impairing its function. For such a reason, the surface tension is 60 mN/m or more and 75 mN/m or less, preferably 68 mN/m or more and 75 mN/m or less, and most preferably 71 mN/m or more and 73 mN/m or less. The surface tension in the present specification is a value at 25° C.

### (Onium Ion)

The surface tension is affected by the onium ion as the smoothing agent for filtration used in the present embodiment. Thus, when the type and concentration of the onium ion are appropriately selected, the surface tension can be maintained in an appropriate range. To maintain the surface tension in a preferable range, it is preferable to select one or more types selected from the group consisting of onium ions having structures represented by the following formulae (1) to (6).

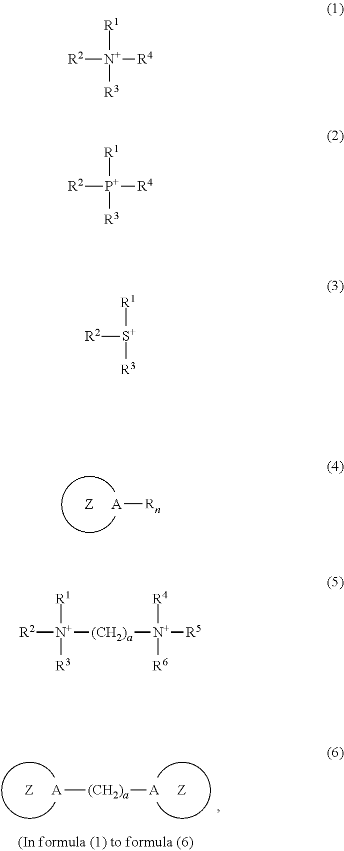

R¹, R², R³, R⁴, R⁵, and R⁶ each independently denote an alkyl group having a carbon number from 2 to 9, an allyl group, an aralkyl group having an alkyl group having a carbon number from 1 to 9, or an aryl group. In an aryl group of the aralkyl group and in a ring of the aryl group, at least one hydrogen is optionally substituted with fluorine, chlorine, an alkyl group having a carbon number from 1 to 9, an alkenyl group having a carbon number from 2 to 9, an alkoxy group having a carbon number from 1 to 9, or an alkenyloxy group having a carbon number from 2 to 9, and in these groups, at least one hydrogen is optionally substituted with fluorine, chlorine, bromine, or iodine.

Examples of the counter anion with respect to the onium ion include a fluoride ion, a chloride ion, a bromide ion, an iodide ion, a hydroxide ion, a nitrate ion, a phosphate ion, a sulfate ion, a hydrogensulfate ion, a methanesulfate ion, a perchlorate ion, a chlorate ion, a chlorite ion, a hypochlorite ion, an orthoperiodate ion, a metaperiodate ion, an iodate ion, an iodite ion, a hypoiodite ion, an acetate ion, a carbonate ion, a hydrogen carbonate ion, a fluoroborate ion, or a trifluoroacetate ion.

A is an ammonium ion or a phosphonium ion.

Z is an aromatic or alicyclic group optionally containing a nitrogen atom, a sulfur atom, or an oxygen atom, and in the aromatic or alicyclic group, carbon or nitrogen optionally has chlorine, bromine, fluorine, iodine, at least one alkyl group having a carbon number from 1 to 9, at least one alkenyloxy group having a carbon number from 2 to 9, an aromatic group optionally substituted with at least one alkyl group having a carbon number from 1 to 9, or an alicyclic group optionally substituted with at least one alkyl group having a carbon number from 1 to 9.

R is chlorine, bromine, fluorine, iodine, an alkyl group having a carbon number from 1 to 9, an allyl group, an aromatic group optionally substituted with at least one alkyl group having a carbon number from 1 to 9, or an alicyclic group optionally substituted with at least one alkyl group having a carbon number from 1 to 9. n is an integer of 1 or 2 and indicates the number of R groups. When n is 2, two R groups are optionally identical to or different from each other, and optionally form a ring.

a is an integer of 1 to 10.)

The longer the hydrocarbon group represented by R in the formulae, the higher the hydrophobicity. Thus, the surface tension tends to decrease when the smoothing agent for filtration contains an onium ion having a longer-chain hydrocarbon group. Meanwhile, when the hydrocarbon chain is too short, the effects of the onium ion, that is, an improvement in surface smoothness and the effect of inhibiting RuO₄ gas, are limited. For such a reason, the carbon number of the hydrocarbon group is preferably within the above range.

The concentration of the onium ion in the treatment liquid of the present embodiment is preferably 1 mass ppm or more and 10000 mass ppm or less. When the amount of the onium ion added is too small, in a case where the treatment liquid for a semiconductor is used for ruthenium, interaction with RuO₄ is weakened and the RuO₄ gas inhibiting effect is reduced. In addition, the amount of the onium ion attached to the metal surface at the time of etching is insufficient, whereby the surface smoothness tends to be lowered. Meanwhile, when the addition amount is too large, the amount of the onium ion adsorbed to the metal surface becomes too large, and the etching rate decreases. In the treatment liquid for a semiconductor of the present embodiment, the halogen oxyacid ion and the onium ion may react with each other to cause a decrease in the concentration of the halogen oxyacid ion. Accordingly, the treatment liquid of the present embodiment contains the onium ion in an amount of preferably 1 mass ppm or more and 10000 mass ppm or less, more preferably 10 mass ppm or more and 5000 mass ppm or less, and still more preferably 50 mass ppm or more and 2000 mass ppm or less. In a case where an onium ion is added, only one type can be added, or two or more types can be added in combination. Even in a case where two or more types of onium ions are contained, the generation of RuO₄ gas can be effectively inhibited as long as the total concentration of the onium ions is in the above-described concentration range.

Examples of such onium ions include chlorocholine ion, trans-2-butene-1,4-bis(triphenylphosphonium ion), 1-hexyl-3-methylimidazolium ion, allyltriphenylphosphonium ion, tetraphenylphosphonium ion, benzyltriphenylphosphonium ion, methyltriphenylphosphonium ion, (2-carboxyethyl)triphenylphosphonium ion, (3-carboxypropyl)triphenylphosphonium ion, (4-carboxybutyl)triphenylphosphonium ion, (5-carboxypentyl)triphenylphosphonium ion, cinnamyltriphenylphosphonium ion, (2-hydroxybenzyl)triphenylphosphonium ion, (1-naphthylmethyl)triphenylphosphonium ion, butyltriphenylphosphonium ion, (tert-butoxycarbonylmethyl)triphenylphosphonium ion, allyltriphenylphosphonium ion, (3-methoxybenzyl)triphenylphosphonium ion, (methoxymethyl)triphenylphosphonium ion, (1-ethoxy-1-oxopropan-2-yl)triphenylphosphonium ion, (3,4-dimethoxybenzyl)triphenylphosphonium ion, methoxycarbonylmethyl(triphenyl)phosphonium ion, (2,4-dichlorobenzyl)triphenylphosphonium ion, (2-hydroxy-5-methylphenyl)triphenylphosphonium ion, (4-chlorobenzyl)triphenylphosphonium ion, (3-chloro-2-hydroxypropyl)trimethylammonium ion, methacroylcholine ion, benzoylcholine ion, benzyldimethylphenylammonium ion, (2-methoxyethoxymethyl)triethylammonium ion, carbamylcholine ion, 1,1′-difluoro-2,2′-bipyridinium bis(tetrafluoroborate), benzyltributylammonium ion, trimethylphenylammonium ion, 5-azoniaspiro[4.4]nonane ion, tributylmethylammonium ion, tetrabutylammonium ion, tetrapentylammonium ion, tetrabutylphosphonium ion, diallyldimethylammonium ion, 1,1-dimethylpiperidinium ion, (2-hydroxyethyl)dimethyl(3-sulfopropyl)ammonium hydroxide, 3-(trifluoromethyl)phenyltrimethylammonium ion, 1,1′-(decane-1,10-diyl)bis[4-aza-1-azoniabicyclo[2.2.2]octane]diion, (3-bromopropyl)trimethylammonium ion, vinylbenzyltrimethylammonium ion, allyltrimethylammonium ion, trimethylvinylammonium ion, choline ion, β-methylcholine ion, and triphenylsulfonium ion. Preferred are one or more types selected from the group consisting of benzyldimethylphenylammonium ion, 1-ethoxy-1-oxopropan-2-yl)triphenylphosphonium ion, 1,1′-(decan-1,10-diyl)bis[4-aza-1-azoniabicyclo[2.2.2]octane]diion, butyltriphenylphosphonium ion, (2-carboxyethyl)triphenylphosphonium ion, (3-carboxypropyl)triphenylphosphonium ion, (4-carboxybutyl)triphenylphosphonium ion, allyltriphenylphosphonium ion, tetraphenylphosphonium ion, and benzyltriphenylphosphonium ion.

As described above, the effects of the onium ion include inhibition of roughening of surface at the time of etching and inhibition of RuO₄ gas (in a case of etching of ruthenium), and in addition, there is also an effect of increasing the number of reuses when used as the semiconductor treatment liquid. In a semiconductor wafer production plant, from the viewpoint of cost reduction, it is common to recycle and reuse a used treatment liquid. In this case, for example, a metal is dissolved in the treatment liquid in etching, and thus the composition of the treatment liquid before use differs from that after use. For example, when ruthenium is etched by the halogen oxyacid ion such as a hypobromite ion, ruthenium is dissolved as RuO₄ under alkaline conditions. In this case, when RuO₄ or RuO₄²⁻ generated by the change of RuO₄ or RuO₄ reacts with the hypobromite ion, the concentration of the hypobromite ion, which is a chemical species effective for etching, decreases. Thus, the etching rate decreases when the number of times of reuse of the treatment liquid increases and when the reuse time lengthens.

However, when an onium ion is contained in the treatment liquid of the present embodiment, the stability at the time of reuse may be improved. That is, in a case where ruthenium is etched, RuO₄ actively reacts with the onium ion, whereby the reaction between RuO₄ and the halogen oxyacid ion such as a hypobromite ion can be inhibited. The onium ion which can be used for such a purpose is preferably a phosphonium ion. In a case of an ammonium ion, there is a concern that an amine is generated by a reaction with the halogen oxyacid ion such as a hypobromite ion, and thus there is a possibility that the amine decomposes the halogen oxyacid ion such as a hypobromite ion. In addition, a phosphonium ion generally has a larger molecular size than an ammonium ion and easily forms an ion pair with RuO₄ generated by dissolution, and thus an effect of inhibiting a reaction between RuO₄⁻ and the halogen oxyacid ion such as a hypobromite ion is also obtained by binding RuO₄⁻.

Examples of such an onium ion include allyltriphenylphosphonium ion, tetraphenylphosphonium ion, trans-2-butene-1,4-bis(triphenylphosphonium ion), benzyltriphenylphosphonium ion, tetrabutylphosphonium ion, tributylhexylphosphonium ion, heptyltriphenylphosphonium ion, cyclopropyltriphenylphosphonium ion, (bromomethyl)triphenylphosphonium ion, and (chloromethyl)triphenylphosphonium ion.

### (Etching Treatment of Semiconductor Wafer)

The treatment liquid of the present embodiment can be used in an etching treatment of a semiconductor wafer. The etching treatment includes a step of bringing the semiconductor wafer into contact with the treatment liquid of the present embodiment.

In a case where the treatment liquid of the present embodiment contains the above-described smoothing agent for filtration, the treatment liquid can be preferably used as an etching solution for a semiconductor wafer. The conditions of the smoothing agent for filtration can be the same as described above.

A wet-etching treatment of ruthenium will be described as an example of the etching treatment using the treatment liquid of the present embodiment. Firstly, a substrate made of a semiconductor (for example, Si) is provided. An oxidation treatment is performed on the provided substrate to form a silicon oxide film on the substrate. Thereafter, an interlayer insulating film is formed from a low dielectric constant (Low-k) film, and via holes are formed at predetermined intervals. After formation of the via holes, ruthenium is formed into a film by thermal CVD. When the ruthenium film is etched using the treatment liquid of the present embodiment, a ruthenium wiring having excellent surface smoothness can be formed in the via holes while inhibiting generation of RuO₄ gas. The metal contained in the semiconductor wafer can be at least one metal selected from Ru, Rh, Ti, Ta, Co, Cr, Hf, Os, Pt, Ni, Mn, Cu, Zr, La, Mo, or W. Among these, ruthenium is not limited to metallic ruthenium and only needs to contain 70 atom % or more of ruthenium. Ruthenium includes a ruthenium alloy, a ruthenium oxide (e.g., ruthenium dioxide or diruthenium trioxide), a nitride, an oxynitride, an intermetallic compound, an ionic compound, and a complex of ruthenium.

The temperature at the time of etching of a metal such as ruthenium (specific examples will be described below) using the treatment liquid of the present embodiment is not particularly limited, and only needs to be determined in consideration of the etching rate of the metal such as ruthenium. In a case where the treatment temperature is high, for example, when ruthenium is etched, the amount of RuO₄ gas increases, and the stability of the halogen oxyacid decreases. Meanwhile, a decrease in the temperature tends to cause a decrease in the etching rate. For such a reason, the temperature for etching the metal such as ruthenium is preferably from 10° C. to 90° C., more preferably from 15° C. to 60° C., and most preferably from 25° C. to 45° C. In a case where the treatment liquid of the present embodiment contains the smoothing agent for filtration, the surface tension at 25° C. is preferably 60 mN/m or more and 75 mN/m or less.

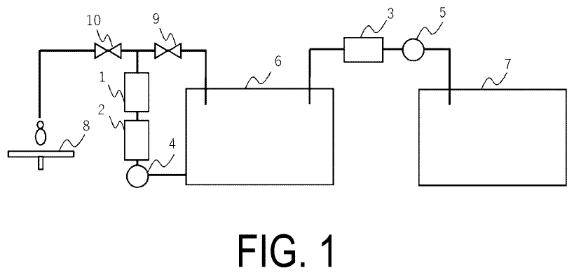

With reference to FIG. 1, when a semiconductor element is produced, the treatment liquid of the present embodiment has an opportunity to pass through filters 1 and 2 or 3. In a case where a valve 10 of FIG. 1 is closed and a valve 9 is opened, a chemical liquid in a chemical cabinet 6 is filtered by passing through the filters 1 and 2 by driving of a pump 4. To remove impurities from the chemical liquid in the chemical cabinet 6 as much as possible, a filtration step of allowing the chemical liquid to pass through the filters 1 and 2 can be performed a plurality of times. The number of filters through which the chemical liquid passes in one filtration step can be, for example, 1 or more, 2, 3, or 4 or more.

When the valve 10 in FIG. 1 is opened, the chemical liquid in the chemical cabinet 6 is supplied to an etching table 8 by driving of the pump 4, and a semiconductor wafer is etched. To replenish the chemical liquid in the chemical cabinet 6, the chemical liquid in a chemical liquid replenishing unit passes through the filter 3 by driving of a pump 5 and is replenished into the chemical cabinet 6.

The chemical liquid described here is the treatment liquid of the present embodiment, and can be a treatment liquid to which the above-described smoothing agent for filtration is added.

A semiconductor element can be produced by a known step used in a method for producing a semiconductor element, for example, one or more steps selected from a wafer fabrication step, an oxide film formation step, a transistor formation step, a wiring formation step, and a CMP step, in addition to the etching treatment of a semiconductor wafer.

### EXAMPLES

The present invention will be described in more detail below by Examples, but the present invention is not limited to these Examples.

### (Production of Trimethylammonium Hypochlorite Solution)

In a 2-L glass three-necked flask (available from Cosmos Bead Co., Ltd.), 209 g of a 25 mass % aqueous tetramethylammonium hydroxide solution was mixed with 791 g of ultrapure water, to prepare a 5.2 mass % aqueous tetramethylammonium hydroxide solution having a CO₂ content of 0.5 ppm. At this time, the pH of the solution was 13.8.

A stirring bar (available from As One Corporation, 30 mm in total length×8 mm in diameter) was then placed in the three-necked flask, and a thermometer protecting tube (available from Cosmos Bead Co., Ltd., bottom-sealed type) and a thermometer were placed through one opening, and, through another opening, the tip end of a PFA tube (F-8011-02, available from Flon Industry) connected to a chlorine gas cylinder and a nitrogen gas cylinder was immersed in the bottom of the solution, such that switching between chlorine gas and nitrogen gas could be made optionally. The remaining one opening was connected to a gas washing bottle (gas washing bottle, model No. 2450/500, available from As One Corporation) filled with a 5 mass % aqueous sodium hydroxide solution. Subsequently, nitrogen gas having a carbon dioxide concentration of less than 1 ppm was introduced through the PFA tube at 0.289 Pa·m³/second (converted at 0° C.) for 20 minutes to purge carbon dioxide in the gas phase. At this time, the carbon dioxide concentration in the gas phase was 1 ppm or less.

Thereafter, a magnetic stirrer (C-MAG HS10, available from As One Corporation) was placed below the three-necked flask, and the stirring bar was rotated at 300 rpm for stirring. While the periphery of the three-necked flask was cooled with ice water, chlorine gas (available from Fujiox Co., Ltd., specification purity 99.4%) was supplied at 0.059 Pa·m³/second (converted at 0° C.) for 180 minutes, to prepare a mixed solution of an aqueous tetramethylammonium hypochlorite solution (hypochlorite ion; equivalent to 3.51 mass %, 0.28 mol/L) and tetramethylammonium hydroxide (equivalent to 0.09 mass %, 0.0097 mol/L). At this time, the solution temperature during the reaction was 11° C.

### (Production of Treatment Liquid)

Treatment liquids having compositions shown in Table 1 were produced by mixing a solution containing a halogen oxyacid ion, a specific metal, a specific ion, ultrapure water, and a pH adjuster in predetermined amounts.

### (Halogen Oxyacid Ion in Treatment Liquid)

In a case where a hypochlorite ion was selected as the halogen oxyacid ion, the tetramethylammonium hypochlorite solution prepared by the above operation was used as a solution containing the halogen oxyacid ion at a predetermined concentration.

In a case where a hypobromite ion or a hypobromite ion and a hypochlorite ion were selected as the halogen oxyacid ion, a predetermined amount of tetramethylammonium bromide (97 mass %, available from Tokyo Chemical Industry Co., Ltd.) was added to the tetramethylammonium hypochlorite solution prepared by the above operation, and the resultant solution was used as a solution containing the halogen oxyacid ion at a predetermined concentration.

In a case where a periodate ion was selected as the halogen oxyacid ion, a solution containing an orthoperiodate ion was used as a solution containing the halogen oxyacid ion at a predetermined concentration.

### (Specific Ion in Treatment Liquid)

A predetermined weight of commercially available sodium chlorate (available from Wako Pure Chemical Industries, Ltd.), sodium chlorite (available from Wako Pure Chemical Industries, Ltd.), hydrogen chloride (35 mass %, available from Kanto Chemical Co., Ltd.), sodium bromate (available from Wako Pure Chemical Industries, Ltd.), sodium bromite (available from Nippon Silica Industries Corporation), hydrogen bromide (47 mass %, available from Tama Chemicals Co., Ltd.), sodium iodate (available from Wako Pure Chemical Industries, Ltd.), hydrogen iodide (55 mass %, available from Wako Pure Chemical Industries, Ltd.), or tetrabutylammonium triiodide (available from Sigma-Aldrich Co.) was added to the treatment liquid in such a manner that the concentration of a chlorate ion, a chloride ion, a bromate ion, a bromite ion, a bromide ion, an iodate ion, an iodide ion, or a triiodide ion, serving as a specific ion, was as shown in Table 1. The cation of sodium chlorate, sodium chlorite, sodium bromate, sodium bromite, sodium iodate, or tetrabutylammonium triiodide was exchanged for a tetramethylammonium ion using an ion exchange resin.

The amount of each specific ion added was measured by using ion chromatography (available from Thermo Fisher Scientific K.K.) to confirm that a predetermined amount of ion was added.

### (Evaluation)

The produced treatment liquids were used to evaluate the surface smoothness of ruthenium and the stability of the etching rate of ruthenium by the above-described methods.

(Evaluation of Surface Smoothness after Etching)

An oxide film was formed on a silicon wafer using a batch-type thermal oxidation furnace, and a 1200 Å (±10%) film of ruthenium was formed on the oxide film using a sputtering method, to yield a ruthenium film before etching. Subsequently, 40 mL of the treatment liquid produced above was provided in a fluororesin-made container having a lid (94.0-mL PFA container, available from As One Corporation). A 10×10 mm piece of the formed ruthenium film having a thickness of 1200 Å was immersed in the chemical liquid at 35° C. for 2 minutes to yield a ruthenium film after etching. The ruthenium surface before and after etching was observed with a field emission scanning electron microscope (JSM-7800F Prime, available from JEOL Ltd.) to determine the presence or absence of roughening of the surface, followed by evaluation based on the following criteria. Roughening of surface was evaluated as A to D in order from the smallest roughening, and evaluations of A to C were all considered to be acceptable and an evaluation of D was considered to be unacceptable.
A: No roughening of surface is observed.
B: Slight roughening of surface is observed.
C: Roughening is observed on the entire surface, but the roughness is shallow
D: Roughening is observed on the entire surface, and the roughness is deep

### (Evaluation of Stability of Etching Rate)

The stability of the etching rate was evaluated using the treatment liquid produced as described above. The sheet resistance was measured with a four-probe resistance measuring instrument (Loresta-GP, available from Mitsubishi Chemical Analytech Co., Ltd.) and converted to a film thickness, and the film thickness was used as the thickness of a ruthenium film before the etching treatment. Subsequently, 40 mL of the treatment liquid produced above was provided in a fluororesin-made container having a lid (94.0-mL PFA container, available from As One Corporation). A 10×10 mm piece of the formed ruthenium film having a thickness of 1200 Å was immersed in a chemical liquid at 35° C. for 2 minutes, and the thickness of the ruthenium film was measured in accordance with the above-described method and taken as the thickness after etching treatment. This was defined as the etching rate immediately after the production of the treatment liquid, and the etching rate was evaluated every week thereafter by the above-described method. The time during which the obtained etching rate was increased or decreased by ±10% or less relative to the etching rate immediately after the production of the treatment liquid was defined as the stability of the etching rate, and the stability was evaluated based on the following criteria. Evaluations A to C are acceptable levels, and an evaluation D is an unacceptable level.
A: 180 days or longer
B: 120 days or longer and 179 days or shorter
C: 60 days or longer and 119 days or shorter
D: 59 days or shorter

### (Comprehensive Evaluation)

The results of both the evaluation of the surface smoothness after etching and the evaluation of the stability of the etching rate obtained above are considered, and evaluation was made according to the following criteria. The effect of the treatment liquid is evaluated as A to D in order from the highest, and evaluations A to C are acceptable levels and an evaluation D is an unacceptable level.
A: Roughening of surface is evaluated as A and the stability is evaluated as A.
B: Either evaluation of roughening of surface or evaluation of the stability includes B, and both the evaluations are within a range of A to C.
C: Either evaluation of roughening of surface or evaluation of the stability includes C, and both the evaluations are within a range of A to C. (Acceptable Level)
D: Either evaluation of roughening of surface or evaluation of the stability includes D.

### (Method for Calculating Hypobromite Ion and Hypochlorite Ion Concentrations)

Hypobromite ion and hypochlorite ion concentrations were measured with an ultraviolet-visible spectrophotometer (UV-2600, available from Shimadzu Corporation). A calibration curve was prepared using an aqueous hypobromite ion solution and aqueous hypochlorite ion solution having known concentrations, and the hypobromite ion and hypochlorite ion concentrations in the produced treatment liquid for a semiconductor were determined. The hypobromite ion and hypochlorite ion concentrations were determined from measurement data when the absorption spectrum was stabilized after production of the treatment liquid.

### Examples 1 to 61 and Comparative Examples 1 to 12

The tests of Examples 1 to 61 and Comparative Examples 1 to 12 were conducted by the method described above. The compositions of the treatment liquids and the respective evaluation results are shown in Tables 1 to 5. The “specific ratio” shown in each of Tables 1 to 4 below is the ratio of the concentration of a specific ion described in the table to the total concentration of Na, K, and Ca contained in the treatment liquid. The “specific ratio” shown in Table 5 below is the ratio of the concentration of a specific ion described in the table to the total concentration of Cr, Ni, and Al contained in the treatment liquid. As shown in Tables 1 to 4, in Comparative Examples 1 to 2, 4 to 5, 7 to 8, and 10 to 11, the etching rate stability was lost due to addition of a chlorite ion, and in Comparative Examples 3, 6, 9, and 12, the surface smoothness was lost due to an excessive amount of a metal. In contrast, it was confirmed that the treatment liquids of the present Examples satisfy the surface smoothness and the etching rate stability by addition of a specific metal and a specific ion. In addition, the results demonstrated that when the concentration of the specific ion increases, the etching rate stability deteriorates, and when the ratio of the specific metal to the specific ion falls within a predetermined range, the surface smoothness and the etching rate stability are more effective. Table 5 shows the results obtained when the metal species added in Examples 1, 19, 33, and 43 were changed from the total concentration of Na, K, and Ca to the total concentration of Cr, Ni, and Al. As shown in Table 5, even when the total concentration of Cr, Ni, and Al is used, the same effect as the result of the total concentration of Na, K, and Ca is obtained. However, as shown in Examples 1, 19, 33, and 43, when the total concentration of Na, K, and Ca is selected, the effect on roughening of surface is higher due to the difference in adsorption caused by the ionization tendency.

TABLE 1

| | | Specific metal | | | | | Specific ratio | | | | |
|---|---|---|---|---|---|---|---|---|---|---|---|
| | | Amount | Amount | Amount | Specific ion | | Specific ion | pH of | Surface | Etching | Compre- |
| | | of Na | of K | of Ca | | Concen- | concentration/ | treatment | smooth- | rate | hensive |
| | | metal | metal | metal | | tration | total concentration | liquid | ness | stability | evalu- |
| | Oxidizing agent | ppt | ppt | ppt | Type | ppm | of specific metals | (25° C.) | (Ru) | (Ru) | ation |
| Example 1 | 0.1 mass % | 12 | 18 | 19 | Bromate | 20 | 4.1 × 10⁵ | 12 | A | A | A |
| | hypobromite ion | | | | ion | | | | | | |
| | 0.05 mass % | | | | | | | | | | |
| | hypochlorite ion | | | | | | | | | | |
| Example 2 | 0.1 mass % | 22 | 43 | 49 | Bromate | 20 ppb | 1.8 × 10² | 12 | A | A | A |
| | hypobromite ion | | | | ion | | | | | | |
| | 0.05 mass % | | | | | | | | | | |
| | hypochlorite ion | | | | | | | | | | |
| Example 3 | 0.1 mass % | 31 | 29 | 43 | Bromate | 1000 | 9.7 × 10⁸ | 12 | A | B | B |
| | hypobromite ion | | | | ion | | | | | | |
| | 0.05 mass % | | | | | | | | | | |
| | hypochlorite ion | | | | | | | | | | |
| Example 4 | 0.1 mass % | 19 | 17 | 11 | Bromate | 20000 | 4.3 × 10⁸ | 12 | A | C | C |
| | hypobromite ion | | | | ion | | | | | | |
| | 0.05 mass % | | | | | | | | | | |
| | hypochlorite ion | | | | | | | | | | |
| Example 5 | 0.1 mass % | 4 | 19 | 12 | Bromate | 20 | 5.3 × 10⁵ | 9 | A | B | B |
| | hypobromite ion | | | | ion | | | | | | |
| | 0.05 mass % | | | | | | | | | | |
| | hypochlorite ion | | | | | | | | | | |
| Example 6 | 3.0 mass % | 21 | 9 | 17 | Bromate | 20 | 4.3 × 10⁵ | 12 | A | B | B |
| | hypobromite ion | | | | ion | | | | | | |
| | 1.5 mass % | | | | | | | | | | |
| | hypochlorite ion | | | | | | | | | | |
| Example 7 | 0.1 mass % | 15 | 16 | 14 | Chloride | 20 ppb | 4.4 × 10² | 12 | A | A | A |
| | hypobromite ion | | | | ion | | | | | | |
| | 0.05 mass % | | | | | | | | | | |
| | hypochlorite ion | | | | | | | | | | |
| Example 8 | 0.1 mass % | 18 | 19 | 18 | Chloride | 20 | 3.6 × 10⁵ | 12 | A | A | A |
| | hypobromite ion | | | | ion | | | | | | |
| | 0.05 mass % | | | | | | | | | | |
| | hypochlorite ion | | | | | | | | | | |
| Example 9 | 0.1 mass % | 17 | 11 | 13 | Chloride | 1000 | 2.4 × 10⁷ | 12 | A | B | B |
| | hypobromite ion | | | | ion | | | | | | |
| | 0.05 mass % | | | | | | | | | | |
| | hypochlorite ion | | | | | | | | | | |
| Example 10 | 0.1 mass % | 21 | 19 | 17 | Chloride | 20000 | 3.5 × 10⁸ | 12 | A | C | C |
| | hypobromite ion | | | | ion | | | | | | |
| | 0.05 mass % | | | | | | | | | | |
| | hypochlorite ion | | | | | | | | | | |
| Example 11 | 0.1 mass % | 19 | 17 | 12 | Chlorate | 20 ppb | 4.2 × 10² | 12 | A | A | A |
| | hypobromite ion | | | | ion | | | | | | |
| | 0.05 mass % | | | | | | | | | | |
| | hypochlorite ion | | | | | | | | | | |
| Example 12 | 0.1 mass % | 16 | 24 | 19 | Chlorate | 20 | 3.5 × 10⁵ | 12 | A | A | A |
| | hypobromite ion | | | | ion | | | | | | |
| | 0.05 mass % | | | | | | | | | | |
| | hypochlorite ion | | | | | | | | | | |
| Example 13 | 0.1 mass % | 25 | 20 | 19 | Chlorate | 1000 | 1.6 × 10⁷ | 12 | A | B | B |
| | hypobromite ion | | | | ion | | | | | | |
| | 0.05 mass % | | | | | | | | | | |
| | hypochlorite ion | | | | | | | | | | |
| Example 14 | 0.1 mass % | 13 | 15 | 25 | Chlorate | 20000 | 3.8 × 10⁸ | 12 | A | C | C |
| | hypobromite ion | | | | ion | | | | | | |
| | 0.05 mass % | | | | | | | | | | |
| | hypochlorite ion | | | | | | | | | | |
| Example 15 | 0.1 mass % | 24 | 13 | 17 | Bromite | 20 ppb | 3.7 × 10² | 12 | A | A | A |
| | hypobromite ion | | | | ion | | | | | | |
| | 0.05 mass % | | | | | | | | | | |
| | hypochlorite ion | | | | | | | | | | |
| Example 16 | 0.1 mass % | 20 | 20 | 22 | Bromite | 20 | 3.2 × 10⁵ | 12 | A | A | A |
| | hypobromite ion | | | | ion | | | | | | |
| | 0.05 mass % | | | | | | | | | | |
| | hypochlorite ion | | | | | | | | | | |
| Example 17 | 0.1 mass % | 19 | 12 | 12 | Bromite | 1000 | 2.3 × 10⁷ | 12 | A | B | B |
| | hypobromite ion | | | | ion | | | | | | |
| | 0.05 mass % | | | | | | | | | | |
| | hypochlorite ion | | | | | | | | | | |
| Example 18 | 0.1 mass % | 17 | 10 | 24 | Bromite | 20000 | 3.9 × 10⁸ | 12 | A | C | C |
| | hypobromite ion | | | | ion | | | | | | |
| | 0.05 mass % | | | | | | | | | | |
| | hypochlorite ion | | | | | | | | | | |
| Comparative | 0.1 mass % | 14 | 18 | 12 | Chlorite | 20 | 4.5 × 10⁵ | 12 | C | D | D |
| Example 1 | hypobromite ion | | | | ion | | | | | | |
| | 0.05 mass % | | | | | | | | | | |
| | hypochlorite ion | | | | | | | | | | |
| Comparative | 0.1 mass % | 329 | 498 | 292 | Chlorite | 20 | 1.8 × 10⁴ | 12 | D | D | D |
| Example 2 | hypobromite ion | | | | ion | | | | | | |
| | 0.05 mass % | | | | | | | | | | |
| | hypochlorite ion | | | | | | | | | | |
| Comparative | 0.1 mass % | 276 | 255 | 319 | Bromate | 40000 | 4.7 × 10⁷ | 12 | D | D | D |
| Example 3 | hypobromite ion | | | | ion | | | | | | |
| | 0.05 mass % | | | | | | | | | | |
| | hypochlorite ion | | | | | | | | | | |

TABLE 2

| | | Specific metal | | | | | Specific ratio | | | | |
|---|---|---|---|---|---|---|---|---|---|---|---|
| | | Amount | Amount | Amount | Specific ion | | Specific ion | pH of | Surface | Etching | Compre- |
| | | of Na | of K | of Ca | | Concen- | concentration/ | treatment | smooth- | rate | hensive |
| | | metal | metal | metal | | tration | total concentration | liquid | ness | stability | evalu- |
| | Oxidizing agent | ppt | ppt | ppt | Type | ppm | of specific metals | (25° C.) | (Ru) | (Ru) | ation |
| Example 19 | 0.1 mass % | 16 | 11 | 17 | Bromide | 20 | 4.5 × 10⁵ | 12 | A | A | A |
| | hypobromite ion | | | | ion | | | | | | |
| Example 20 | 0.1 mass % | 29 | 48 | 47 | Bromide | 20 ppb | 1.6 × 10² | 12 | A | A | A |
| | hypobromite ion | | | | ion | | | | | | |
| Example 21 | 0.1 mass % | 27 | 42 | 49 | Bromide | 1000 | 8.5 × 10⁶ | 12 | A | B | B |
| | hypobromite ion | | | | ion | | | | | | |
| Example 22 | 0.1 mass % | 23 | 14 | 8 | Bromide | 20000 | 4.4 × 10⁸ | 12 | A | C | C |
| | hypobromite ion | | | | ion | | | | | | |
| Example 23 | 0.1 mass % | 14 | 31 | 4 | Bromide | 20 | 4.8 × 10⁵ | 9 | A | A | A |
| | hypobromite ion | | | | ion | | | | | | |
| Example 24 | 3.0 mass % | 23 | 12 | 7 | Bromide | 20 | 4.8 × 10⁵ | 12 | A | B | B |
| | hypobromite ion | | | | ion | | | | | | |
| Example 25 | 0.1 mass % | 16 | 14 | 24 | Bromate | 20 ppb | 3.7 × 10² | 12 | A | A | A |
| | hypobromite ion | | | | ion | | | | | | |
| Example 26 | 0.1 mass % | 25 | 14 | 20 | Bromate | 20 | 3.5 × 10⁵ | 12 | A | A | A |
| | hypobromite ion | | | | ion | | | | | | |
| Example 27 | 0.1 mass % | 15 | 21 | 22 | Bromate | 1000 | 1.7 × 10⁷ | 12 | A | B | B |
| | hypobromite ion | | | | ion | | | | | | |
| Example 28 | 0.1 mass % | 12 | 14 | 13 | Bromate | 20000 | 5.1 × 10⁸ | 12 | A | C | C |
| | hypobromite ion | | | | ion | | | | | | |
| Example 29 | 0.1 mass % | 10 | 13 | 19 | Bromite | 20 ppb | 4.8 × 10² | 12 | A | A | A |
| | hypobromite ion | | | | ion | | | | | | |
| Example 30 | 0.1 mass % | 13 | 20 | 22 | Bromite | 20 | 3.6 × 10⁵ | 12 | A | A | A |
| | hypobromite ion | | | | ion | | | | | | |
| Example 31 | 0.1 mass % | 24 | 14 | 18 | Bromite | 1000 | 1.8 × 10⁷ | 12 | A | B | B |
| | hypobromite ion | | | | ion | | | | | | |
| Example 32 | 0.1 mass % | 14 | 13 | 12 | Bromite | 20000 | 5.1 × 10⁸ | 12 | A | C | C |
| | hypobromite ion | | | | ion | | | | | | |
| Comparative | 0.1 mass % | 15 | 21 | 11 | Chlorite | 20 | 4.3 × 10⁵ | 12 | C | D | D |
| Example 4 | hypobromite ion | | | | ion | | | | | | |
| Comparative | 0.1 mass % | 399 | 401 | 287 | Chlorite | 20 | 1.8 × 10⁴ | 12 | D | D | D |
| Example 5 | hypobromite ion | | | | ion | | | | | | |
| Comparative | 0.1 mass % | 291 | 288 | 272 | Bromate | 40000 | 4.7 × 10⁷ | 12 | D | D | D |
| Example 6 | hypobromite ion | | | | ion | | | | | | |

TABLE 3

| | | Specific metal | | | | | Specific ratio | | | | |
|---|---|---|---|---|---|---|---|---|---|---|---|
| | | Amount | Amount | Amount | Specific ion | | Specific ion | pH of | Surface | Etching | Compre- |
| | | of Na | of K | of Ca | | Concen- | concentration/ | treatment | smooth- | rate | hensive |
| | | metal | metal | metal | | tration | total concentration | liquid | ness | stability | evalu- |
| | Oxidizing agent | ppt | ppt | ppt | Type | ppm | of specific metals | (25° C.) | (Ru) | (Ru) | ation |
| Example 33 | 0.05 mass % | 9 | 12 | 19 | Chloride | 20 | 5.0 × 10⁵ | 12 | A | A | A |
| | hypochlorite ion | | | | ion | | | | | | |
| Example 34 | 0.05 mass % | 47 | 32 | 33 | Chloride | 20 ppb | 1.8 × 10² | 12 | A | A | B |
| | hypochlorite ion | | | | ion | | | | | | |
| Example 35 | 0.05 mass % | 17 | 12 | 21 | Chloride | 1000 | 2.0 × 10⁷ | 12 | A | B | B |
| | hypochlorite ion | | | | ion | | | | | | |
| Example 36 | 0.05 mass % | 16 | 9 | 12 | Chloride | 20000 | 5.8 × 10⁸ | 12 | A | C | C |
| | hypochlorite ion | | | | ion | | | | | | |
| Example 37 | 0.05 mass % | 22 | 12 | 13 | Chloride | 20 | 4.3 × 10⁵ | 9 | A | B | B |
| | hypochlorite ion | | | | ion | | | | | | |
| Example 38 | 1.5 mass % | 19 | 18 | 11 | Chloride | 20 | 4.2 × 10⁵ | 12 | A | B | B |
| | hypochlorite ion | | | | ion | | | | | | |
| Example 39 | 0.05 mass % | 14 | 22 | 14 | Chlorate | 20 ppb | 4.0 × 10² | 12 | A | A | A |
| | hypochlorite ion | | | | ion | | | | | | |
| Example 40 | 0.05 mass % | 15 | 13 | 15 | Chlorate | 20 | 4.7 × 10⁵ | 12 | A | A | A |
| | hypochlorite ion | | | | ion | | | | | | |
| Example 41 | 0.05 mass % | 13 | 10 | 16 | Chlorate | 1000 | 2.6 × 10⁷ | 12 | A | B | B |
| | hypochlorite ion | | | | ion | | | | | | |
| Example 42 | 0.05 mass % | 13 | 24 | 17 | Chlorate | 20000 | 3.7 × 10⁸ | 12 | A | C | C |
| | hypochlorite ion | | | | ion | | | | | | |
| Comparative | 0.05 mass % | 17 | 8 | 15 | Chlorite | 20 | 5.0 × 10⁵ | 12 | C | D | D |
| Example 7 | hypochlorite ion | | | | ion | | | | | | |
| Comparative | 0.05 mass % | 397 | 393 | 404 | Chlorite | 20 | 1.7 × 10⁴ | 12 | D | D | D |
| Example 8 | hypochlorite ion | | | | ion | | | | | | |
| Comparative | 0.05 mass % | 298 | 277 | 301 | Chlorate | 40000 | 4.6 × 10⁷ | 12 | D | D | D |
| Example 9 | hypochlorite ion | | | | ion | | | | | | |

TABLE 4

| | | Specific metal | | | | | Specific ratio | | | | |
|---|---|---|---|---|---|---|---|---|---|---|---|
| | | Amount | Amount | Amount | Specific ion | | Specific ion | pH of | Surface | Etching | Compre- |
| | | of Na | of K | of Ca | | Concen- | concentration/ | treatment | smooth- | rate | hensive |
| | | metal | metal | metal | | tration | total concentration | liquid | ness | stability | evalu- |
| | Oxidizing agent | ppt | ppt | ppt | Type | ppm | of specific metals | (25° C.) | (Ru) | (Ru) | ation |
| Example 43 | 0.3 mass % | 11 | 14 | 19 | Iodide ion | 20 | 4.5 × 10⁵ | 9 | A | A | A |
| | orthoperiodate | | | | | | | | | | |
| | ion | | | | | | | | | | |
| Example 44 | 0.3 mass % | 42 | 45 | 21 | Iodide ion | 20 ppb | 1.9 × 10² | 9 | A | A | B |
| | orthoperiodate | | | | | | | | | | |
| | ion | | | | | | | | | | |
| Example 45 | 0.3 mass % | 12 | 10 | 18 | Iodide ion | 1000 | 2.5 × 10⁷ | 9 | A | B | B |
| | orthoperiodate | | | | | | | | | | |
| | ion | | | | | | | | | | |
| Example 46 | 0.3 mass % | 12 | 18 | 17 | Iodide ion | 20000 | 4.3 × 10⁸ | 9 | A | C | C |
| | orthoperiodate | | | | | | | | | | |
| | ion | | | | | | | | | | |
| Example 47 | 5.0 mass % | 16 | 4 | 12 | Iodide ion | 20 | 6.3 × 10⁵ | 9 | A | A | A |
| | orthoperiodate | | | | | | | | | | |
| | ion | | | | | | | | | | |
| Example 48 | 0.3 mass % | 0.5 | 0.2 | 0.3 | Iodide ion | 20 | 2.0 × 10⁷ | 9 | A | A | A |
| | orthoperiodate | | | | | | | | | | |
| | ion | | | | | | | | | | |
| Example 49 | 0.3 mass % | 45 | 38 | 31 | Iodide ion | 1000 | 8.8 × 10⁶ | 10 | A | B | B |
| | orthoperiodate | | | | | | | | | | |
| | ion | | | | | | | | | | |
| Example 50 | 0.3 mass % | 24 | 15 | 23 | Triiodide | 20 ppb | 3.2 × 10² | 9 | A | A | A |
| | orthoperiodate | | | | ion | | | | | | |
| | ion | | | | | | | | | | |
| Example 51 | 0.3 mass % | 25 | 24 | 10 | Triiodide | 20 | 3.4 × 10⁵ | 9 | A | A | A |
| | orthoperiodate | | | | ion | | | | | | |
| | ion | | | | | | | | | | |
| Example 52 | 0.3 mass % | 13 | 24 | 18 | Triiodide | 1000 | 1.8 × 10⁷ | 9 | A | B | B |
| | orthoperiodate | | | | ion | | | | | | |
| | ion | | | | | | | | | | |
| Example 53 | 0.3 mass % | 12 | 21 | 15 | Triiodide | 20000 | 4.2 × 10⁸ | 9 | A | C | C |
| | orthoperiodate | | | | ion | | | | | | |
| | ion | | | | | | | | | | |
| Example 54 | 0.3 mass % | 18 | 12 | 14 | Iodate ion | 20 ppb | 4.5 × 10² | 9 | A | A | A |
| | orthoperiodate | | | | | | | | | | |
| | ion | | | | | | | | | | |
| Example 55 | 0.3 mass % | 13 | 11 | 16 | Iodate ion | 20 | 5.0 × 10⁵ | 9 | A | A | A |
| | orthoperiodate | | | | | | | | | | |
| | ion | | | | | | | | | | |
| Example 56 | 0.3 mass % | 18 | 25 | 11 | Iodate ion | 1000 | 1.9 × 10⁷ | 9 | A | B | B |
| | orthoperiodate | | | | | | | | | | |
| | ion | | | | | | | | | | |
| Example 57 | 0.3 mass % | 11 | 19 | 22 | Iodate ion | 20000 | 3.8 × 10⁸ | 9 | A | C | C |
| | orthoperiodate | | | | | | | | | | |
| | ion | | | | | | | | | | |
| Comparative | 0.3 mass % | 8 | 18 | 11 | Chlorite | 20 | 5.4 × 10⁵ | 9 | C | D | D |
| Example 10 | orthoperiodate | | | | ion | | | | | | |
| | ion | | | | | | | | | | |
| Comparative | 0.3 mass % | 507 | 393 | 298 | Chlorite | 20 | 1.7 × 10⁴ | 9 | D | D | D |
| Example 11 | orthoperiodate | | | | ion | | | | | | |
| | ion | | | | | | | | | | |
| Comparative | 0.3 mass % | 314 | 255 | 294 | Iodate ion | 40000 | 4.6 × 10⁷ | 9 | D | D | D |
| Example 12 | orthoperiodate | | | | | | | | | | |
| | ion | | | | | | | | | | |

TABLE 5

| | | Specific metal | | | | | Specific ratio | | | | |
|---|---|---|---|---|---|---|---|---|---|---|---|
| | | Amount | Amount | Amount | Specific ion | | Specific ion | pH of | Surface | Etching | Compre- |
| | | of Cr | of Ni | of Al | | Concen- | concentration/ | treatment | smooth- | rate | hensive |
| | | metal | metal | metal | | tration | total concentration | liquid | ness | stability | evalu- |
| | Oxidizing agent | ppt | ppt | ppt | Type | ppm | of specific metals | (25° C.) | (Ru) | (Ru) | ation |
| Example 58 | 0.1 mass % | 18 | 19 | 9 | Bromate | 20 | 4.1 × 10⁵ | 12 | A | A | A |
| | hypobromite ion | | | | ion | | | | | | |
| | 0.05 mass % | | | | | | | | | | |
| | hypochlorite ion | | | | | | | | | | |
| Example 59 | 0.1 mass % | 15 | 14 | 18 | Bromide | 20 | 4.5 × 10⁵ | 12 | A | A | A |
| | hypobromite ion | | | | ion | | | | | | |
| Example 60 | 0.05 mass % | 21 | 8 | 13 | Chloride | 20 | 5.0 × 10⁵ | 12 | A | A | A |
| | hypochlorite ion | | | | ion | | | | | | |
| Example 61 | 0.3 mass % | 18 | 13 | 12 | Iodide | 20 | 4.5 × 10⁵ | 9 | A | A | A |
| | orthoperiodate | | | | ion | | | | | | |
| | ion | | | | | | | | | | |
| Comparative | 0.1 mass % | 201 | 212 | 203 | Bromate | 20 | 3.2 × 10⁴ | 12 | D | D | D |
| Example 13 | hypobromite ion | | | | ion | | | | | | |
| | 0.05 mass % | | | | | | | | | | |
| | hypochlorite ion | | | | | | | | | | |
| Comparative | 0.1 mass % | 216 | 221 | 209 | Bromide | 20 | 3.1 × 10⁴ | 12 | D | D | D |
| Example 14 | hypobromite ion | | | | ion | | | | | | |
| Comparative | 0.05 mass % | 214 | 204 | 202 | Chloride | 20 | 3.2 × 10⁴ | 12 | D | D | D |
| Example 15 | hypochlorite ion | | | | ion | | | | | | |
| Comparative | 0.3 mass % | 203 | 202 | 208 | Iodide | 20 | 3.3 × 10⁴ | 10 | D | D | D |
| Example 16 | orthoperiodate | | | | ion | | | | | | |
| | ion | | | | | | | | | | |

### Examples 62 to 65

Similar to the method for forming a ruthenium film, firstly, an oxide film was formed on a silicon wafer using a batch-type thermal oxidation furnace, and then a 1200 Å (±10%) film of a transition metal (W, Mo) was formed on the oxide film by a sputtering method. The sheet resistance was measured with a four-probe resistance measuring instrument (Loresta-GP, available from Mitsubishi Chemical Analytech Co., Ltd.) and converted to a film thickness.

The treatment liquids having the same compositions as in Examples 1, 19, 33, and 43 were used to evaluate the surface smoothness of a treated portion of the transition metal film (W, Mo) formed by the above method and the stability of the etching rate in the same manner as in Examples 1 to 61.

TABLE 6

| | | Specific metal | | | | | Specific ratio | | | | | |
|---|---|---|---|---|---|---|---|---|---|---|---|---|
| | | Amount | Amount | Amount | Specific ion | | Specific ion | pH of | W | | Mo | |
| | | of Na | of K | of Ca | | Concen- | concentration/ | treatment | Surface | Etching | Surface | Etching |
| | Treatment | metal | metal | metal | | tration | total concentration | liquid | smooth- | rate | smooth- | rate |
| | liquid | ppt | ppt | ppt | Type | ppm | of specific metals | (25° C.) | ness | stability | ness | stability |
| Example | 0.1 mass % | 12 | 18 | 19 | Bromate | 20 | 4.1 × 10⁵ | 12 | A | A | A | A |
| 62 | hypobromite | | | | ion | | | | | | | |
| | ion | | | | | | | | | | | |
| | 0.05 mass % | | | | | | | | | | | |
| | hypochlorite | | | | | | | | | | | |
| | ion | | | | | | | | | | | |
| Example | 0.1 mass % | 16 | 11 | 17 | Bromide | 20 | 4.5 × 10⁵ | 12 | A | A | A | A |
| 63 | hypobromite | | | | ion | | | | | | | |
| | ion | | | | | | | | | | | |
| Example | 0.05 mass % | 9 | 12 | 19 | Chloride | 20 | 5.0 × 10⁵ | 12 | B | A | B | B |
| 64 | hypochlorite | | | | ion | | | | | | | |
| | ion | | | | | | | | | | | |
| Example | 0.3 mass % | 11 | 14 | 19 | Iodide | 20 | 4.5 × 10⁵ | 9 | A | A | A | A |
| 65 | orthoperiodate | | | | ion | | | | | | | |
| | ion | | | | | | | | | | | |

### REFERENCE SIGNS LIST

1 Filter 1
2 Filter 2
3 Filter 3
4 Pump 1
5 Pump 2
6 Chemical cabinet
7 Chemical liquid replenishing unit
8 Etching table
9 Valve 1
10 Valve 2

1. A treatment liquid for a semiconductor to be used for removing a transition metal-containing substance on a substrate, the treatment liquid for a semiconductor comprising:
at least one halogen oxyacid ion selected from the group consisting of a hypobromite ion, a hypochlorite ion, and a periodate ion;
at least one ion selected from the group consisting of a bromide ion, a bromite ion, a bromate ion, a chloride ion, a chlorate ion, an iodate ion, an iodide ion, and a triiodide ion; and
at least one metal selected from the group consisting of Ca, Na, K, Cr, Ni, and Al, wherein a concentration of any one metal of Ca, Na, K, Cr, Ni, or Al is 0.1 mass ppt or more and 200 mass ppt or less.

2. The treatment liquid for a semiconductor according to claim 1, wherein
a ratio of a concentration of any one ion of a bromide ion, a bromite ion, a bromate ion, a chloride ion, or a chlorate ion to a concentration of any one metal of Ca, Na, K, Cr, Ni, or Al is 1 or more and 1×10⁸ or less, and
a hypobromite ion is contained.

3. The treatment liquid for a semiconductor according to claim 1, wherein the metal is Ca, Na, and K.

4. The treatment liquid for a semiconductor according to claim 1, comprising:
at least one ion selected from the group consisting of a bromide ion, a bromite ion, and a bromate ion;
at least one metal selected from the group consisting of Ca, Na, and K; and
a hypobromite ion.

5. The treatment liquid for a semiconductor according to claim 3, wherein a pH of the treatment liquid for a semiconductor is 10.0 or higher and 13.0 or lower.

6. The treatment liquid for a semiconductor according to claim 3, comprising a bromate ion, wherein
a ratio of a concentration of a bromate ion to a total concentration of Ca, Na, and
K is 1 or more and 1×10⁸ or less.

7. The treatment liquid for a semiconductor according to claim 3, comprising at least one ion selected from the group consisting of a bromide ion, a bromite ion, and a bromate ion, wherein
a ratio of a concentration of a bromide ion, a bromite ion, or a bromate ion to a total concentration of Cr, Ni, and Al is 1 or more and 1×10⁸ or less.

8. The treatment liquid for a semiconductor according to claim 1, wherein
a ratio of a concentration of any one ion of a chloride ion or a chlorate ion to a concentration of any one metal of Ca, Na, K, Cr, Ni, or Al is 1 or more and 1×10⁸ or less, and
a hypochlorite ion is contained.

9. The treatment liquid for a semiconductor according to claim 1, comprising:
at least one ion selected from the group consisting of a chloride ion and a chlorate ion;
at least one metal selected from the group consisting of Ca, Na, and K; and
a hypochlorite ion.

10. The treatment liquid for a semiconductor according to claim 8, wherein a pH of the treatment liquid for a semiconductor is 10.0 or higher and 13.0 or lower.

11. The treatment liquid for a semiconductor according to claim 8, comprising a chlorate ion, wherein
a ratio of a concentration of a chlorate ion to a total concentration of Ca, Na, and K is 1 or more and 1×10⁸ or less.

12. The treatment liquid for a semiconductor according to claim 8, comprising a chloride ion, wherein
a ratio of a concentration of a chloride ion to a total concentration of Cr, Ni, and Al is 1 or more and 1×10⁸ or less.

13. The treatment liquid for a semiconductor according to claim 1, wherein
a ratio of a concentration of any one ion of an iodate ion, an iodide ion, or a triiodide ion to a concentration of any one metal of Ca, Na, K, Cr, Ni, or Al is 1 or more and 1×10⁸ or less, and
a periodate ion is contained.

14. The treatment liquid for a semiconductor according to claim 1, comprising:
at least one ion selected from the group consisting of an iodate ion, an iodide ion, and a triiodide ion;
at least one metal selected from the group consisting of Ca, Na, and K; and
a periodate ion.

15. The treatment liquid for a semiconductor according to claim 13, wherein a pH of the treatment liquid for a semiconductor is 8.5 or higher and 11.0 or lower.

16. The treatment liquid for a semiconductor according to claim 14, comprising an iodate ion, wherein
a ratio of a concentration of an iodate ion to a total concentration of Ca, Na, and K is 1 or more and 1×10⁸ or less.

17. The treatment liquid for a semiconductor according to claim 14, comprising an iodide ion, wherein
a ratio of a concentration of an iodide ion to a total concentration of Cr, Ni, and Al is 1 or more and 1×10⁸ or less.
